(19) United States
(12) Patent Application Publication
(10) Pub. No.: US 2013/0033159 A1
(43) Pub. Date: Feb. 7, 2013

(54) COOLING DEVICE, IN PARTICULAR FOR A CONTROL CABINET

(71) Applicants: Manfred Immel, Mittenaar (DE); Joachim Maul, Ehringshausen (DE)

(72) Inventors: Manfred Immel, Mittenaar (DE); Joachim Maul, Ehringshausen (DE)

(73) Assignee: RITTAL GMBH & CO. KG, HERBORN (DE)

(21) Appl. No.: 13/261,380

(22) PCT Filed: Jan. 13, 2011
(86) PCT No.: PCT/EP11/50378

§ 371 Date: Aug. 16, 2012

(30) Foreign Application Priority Data
Jan. 26, 2010 (DE) 10 2010 000 198.8

(51) Int. Cl. H05K 7/20

(52) U.S. Cl. 312/236

(57) ABSTRACT

The invention relates to a cooling device, in particular for a control cabinet, having a housing which comprises an opening into which a fan assembly having a support and a fan can be inserted, wherein the support can be detachably connected to the housing. With such a cooling device, easy installation or removal of the fan assembly is achieved in that the support is pivotally connected to the housing via a hinge assembly having hinge pins and a pivoted receptacle, and in that the support can be pivoted between an installation position and a parking position.

The invention relates to a cooling device, in particular for a control cabinet having a housing which comprises an opening into which a fan assembly having a support and a fan can be inserted, wherein the support can be detachably connected to the housing.

Such fan assemblies may be obtained in many different embodiments. Commonly, the fan is screwed to the support, and the device thus produced is inserted into an opening of the housing of the cooling device. Linkage between the fan assembly and the housing of the cooling device is established by means of bolted connections. In a maintenance situation it may occur that the fan must be inspected or exchanged. To this end, the fan assembly is unscrewed from the housing and removed. Then, the plug connection via which the fan is supplied with electrical energy from the cooling device must be disconnected. If necessary, also additional control wires must be disconnected. Subsequently, the fan assembly can be removed. This procedure is in particular cumbersome if the available space is small or very heavy fans are installed.

It the object of the invention to provide a cooling device of the type mentioned in the introductory for which installation or de-installation, respectively, of the fan assembly can be easily performed.

This object is solved in that the support is pivotally connected to the housing via a hinge assembly having at least one hinge pin and at least one hinge receptacle and that the support can be pivoted between an installation position and a parking position.

In the installation position, the support together with the fan may be safely fixed to the cooling device. If now the fan must be made accessible for maintenance purposes, it may be pivoted with the aid of the hinge connection into the parking position. In that parking position, the assembly man may easily disconnect the electrical plug connection to the cooling device. Then, he may lift the fan assembly from the cooling device and, if necessary, install a new fan assembly, which is initially hung in the parking position. Then, the electrical wire connection is established, the fan assembly is pivoted into the installation position and fixed to the housing.

According to a preferred variant of the invention, it may provided that the hinge pin is displaceable within an elongated hole-like hinge receptacle and that the hinge receptacle comprises an insertion section through which the hinge pin can be moved into or out of the hinge receptacle. This embodiment allows a simple and targeted installation or de-installation, respectively, of the fan assembly.

A further variant of the invention may be characterized in that in the installation position of the support, the hinge pin is held in a parking receptacle of the hinge receptacle and that in the hinged down position of the support, the hinge pin is displaced into a pivoted receptacle and is form-fittingly held therein. A reliable securing of the fan assembly is achieved by that formfitting connection.

A unique de-installation or installation, respectively, of the fan assembly may also be achieved in that the hinge receptacle comprises a slide guide in which the hinge pin can be displaced between a position associated with the installation position and a de-installation position.

The hinge connection may be produced in a very simple way in that the housing comprises a wall delimited by two opposite rims, that the rims are bent from the wall and extend therefrom on the back side and that the rims respectively comprise either a hinge receptacle or a hinge pin.

The number of different parts of the fan assembly may be reduced if it is provided that the support comprises a ventilation grille integrally molded thereto. The support may be embodied in particular as a plastic injection die-cast part.

It is also possible that the support comprises an air outlet cross section which is delimited by a nozzle flange integrally molded to the support. Air may be streamlined guided to the fan via the nozzle flange. In order to fix the fan to the support with small number of different parts, a preferred embodiment of the invention is such that the support comprises screw domes protruding from its rear side by which a support plate is connected and that the support plate receives the fan exchangeably.

A cooling device according to the invention may also be characterized in that the support comprises a cover which at least partly covers the opening of the housing, that side parts are directly or indirectly molded to the cover which extend beyond the cover on its back side and which protrude through the opening in an installed state of the support and that the side parts carry the hinge pins or the hinge receptacles.

A space-saving construction where the fan assembly does not too much extend beyond the front side of the housing may be achieved if it is provided that the pivot axis of the pivot linkage extends in the region of the back side of the cover of the support. In particular, the pivot axis may extend at the lower horizontal rim of the fan assembly.

A secure fixing of the cooling device is achieved in a simple way in that the support can be screw-fastened on opposite sides to the housing while resting at a front side of a wall of the housing with one side and resting at a back side with the other side. By this means, the fan assembly may be tensioned against the wall of the housing.

The invention will below explain in detail with the aid of an exemplary embodiment illustrated in the drawings. It is shown in:

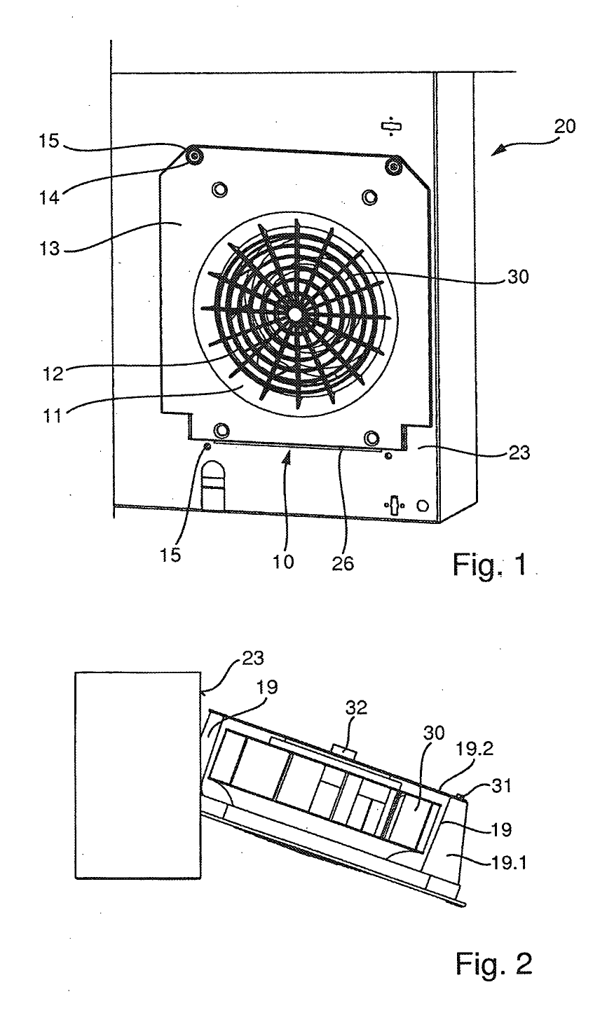

FIG. 1 in a perspective front view a part of a housing of a cooling device with a fan assembly in an installation position;

FIG. 2 the arrangement of FIG. 1 in a side view and vertical section with hinged down fan assembly brought into parking position;

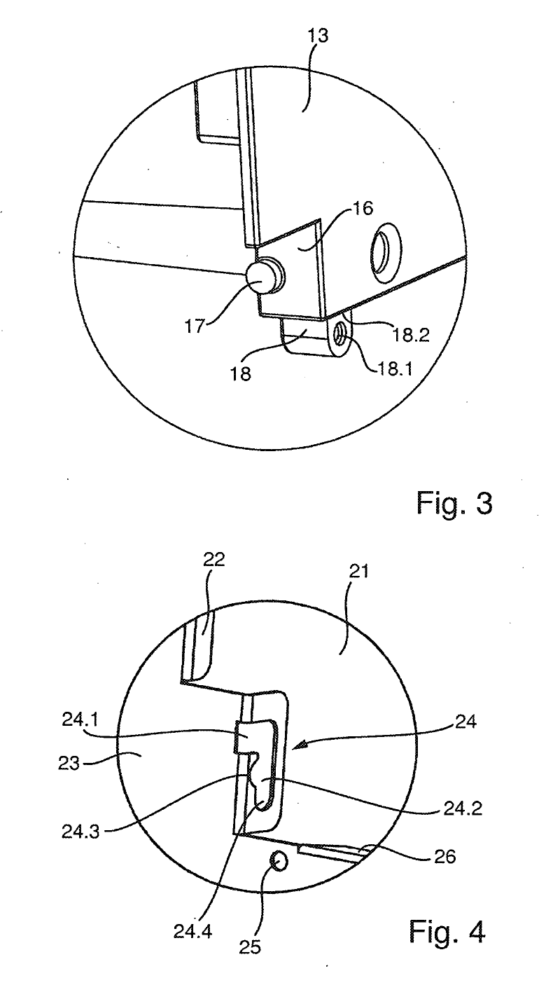

FIG. 3 in a perspective detailed view a lower horizontal region of the support;

FIG. 4 in a perspective view a part of the housing of the cooling device; and

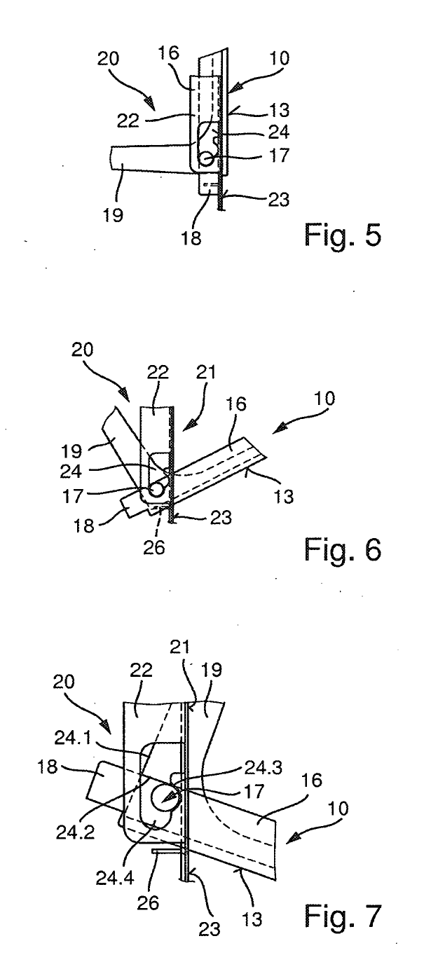

FIGS. 5 to 7 a motion sequence illustrating pivoting of the fan assembly from the installation position into the parking position.

FIG. 1 shows a section of a cooling device which may be mounted to a control cabinet. Such cooling devices may, for example, installed at vertical side walls or on the roof of a control cabinet. Generally, they comprise one or two separated cooling circuits respectively associated to a fan 30. Fan 30 delivers air through the cooling circuit and thus allows heat transfer between the delivered air and a heat exchanger associated with the cooling circuit. As illustrated in FIG. 1, housing 20 of the cooling device comprises a wall 23 which carries a fan assembly. The fan assembly includes a support 10 and, as illustrated by FIG. 2, a fan 30. Support 10 possesses a flat cover 13 which encloses an air outlet area by means of a continuous nozzle flange 11. Nozzle flange 11 is embodied as convexially arced flow area which is integrally connected with support 10. As it is shown in more detail in FIG. 1, a ventilation grille 12 is integrally molded to the nozzle flange 11 which prevents an access to a fan 30 arranged behind it.

FIG. 2 illustrates fastening of fan 30 to support 10. As can be seen in this illustration, screw domes 19 are molded to the back side of support 10 which hold a fixing plate 19.2 parallel and spaced apart from wall 23. Fixing plate 19.2 is connected with screw domes 19 by means of fastening screws 31. In order to safely to absorb vibrations of support 10 occurring during operation, stiffening ribs 19.1 are provided which connect screw domes 19 integrally with cover 13. Fixing plate 19.2 carries fan 30 and aligns it with nozzle flange 11.

In FIG. 3, the lower horizontal rim region of support 10 may be better recognized as an enlarged detail. As illustrated in this drawing, support 10 comprises side parts 16 at its vertical rims which are molded to cover 13 and extend back perpendicular thereto. Side parts 16 are equipped with hinge pins 17 molded thereto. Each side part 16 carries one hinge pin 17, the central longitudinal axes thereof form a common pivot axis. Support 10 further comprises a lower horizontal rim 18.2 which is perpendicularly molded to cover 13. Lower horizontal rim 18.2 respectively carries a tap 18 in corner sections associated with hinge pins 17 which is equipped with a screw receptacle 18.1 shaped as a through bore-hole.

FIG. 4 further illustrates the embodiment of housing 20 in the region of opening 21. As may be recognized in this illustration, opening 21 is laterally delimited by two vertical rims 22 which are bent perpendicularly from wall 23 to the back side. A respective hinge receptacle 24 is worked into rims 22. Hinge receptacle 24 is formed elongated hole like and comprises an insertion section 24.1 merging into a vertical slide guide 24.2 of the elongated hole. Slide guide 24.2 terminates in a lower parking receptacle 24.4. In a region between parking receptacle 24.4 and insertion section 24.1 a pivoted receptacle 24.3 is shaped as a lateral indentation into the hinge receptacle. The lower horizontal rim of the opening 21 is delimited by a horizontal bent 26. This bent extends perpendicular to wall 23 and is bent rearward therefrom.

Below, the procedure of installing the fan assembly in housing 20 of the cooling device is described. Initially, the two hinge pins 17 of the fan assembly are pushed into the insertion sections 24.1 of hinge receptacle 24. Thus, hinge pins 17 reach the region of slide guides 24.2. Supported by the gravity of the fan assembly, it may be lowered with in slide guide 24.2 in a direction vertically downwards. Thereby, cover 13 of support 10 abuts the lower horizontal bent 26 of the housing. In this position, inertia is created by the weight of the fan assembly pivoting around the pivot axis. Thereby, the effective lever arm between pivot axis of hinge pin 17 and the distance of the abut position between bent 26 and wall 23 is formed. The intertia holds hinge pins 17 in a form-fitting manner within pivoted receptacle 24.3. Such safe support of fan assembly allows an assembly man to connect the electrical connection 32 of fan 30 to a cable of the cooling device. Then, the fan assembly may be pivoted upwards from its parking position which is illustrated in FIGS. 2 and 7, wherein the pivoting is accomplished around the pivot axis resulting from the hinge connection.

FIG. 6 shows the fan assembly in a partly pivoted position. As can be seen therefrom, hinge pins 17 move out of pivoted receptacle 24.3 while pivoting the fan assembly upwards and slide into parking receptacle 24.4. In this parking receptacle 24.4, pivoting can be proceeded with until the fan assembly reaches its vertical position and thus the installation position. Thereby, the side parts 16 of support 10 are opposite to rims 22 of housing 20. Tabs 18 abut to wall 23 of housing 20 at the back side such that their screw receptacles 18.1 are aligned with openings of wall 23. Fastening screws 15 (see FIG. 1) may be guided through these openings and screwed into screw receptacles 18.1.

Two further fastening receptacles 14 are provided at the horizontal upper rim of support 10, as further illustrated in FIG. 1. Fastening screws 15 may be inserted therethrough and screwed into threaded receptacles of housing 20. In this way, the fan assembly is reliably fixed with the aid of four fastening screws 15. This type of fastening is chosen when strong mechanical loads act on the cooling device for example when dynamic alternating loads are acting. For reduced requirements to the type of fastening, it may be sufficient that merely the two upper fastening screws 15 are provided and that the fan assembly is supported at its lower horizontal rim solely with hinge pins 17 in hinge receptacle 24.

De-installation of the fan assembly is accomplished in an installation sequence which is reversed to that previously described. Initially, the four fastening screws 15 are removed. Then, the fan assembly may be hinged down from its installation position according to FIG. 1 or 5, respectively (see FIG. 6). Thereby, support 10 abuts bent 26 with its cover 13. Thus, a lever arm and an inertia are produced with lift hinge pins 17 from parking receptacle 24.4 and into pivoted receptacle 24.3. A secure fixing of the fan assembly in the parking position according to FIG. 2 or 7, respectively, as explained before, is achieved. The fan assembly may be moved from this parking position vertically upwards within slide guide 24.2 until hinge pins 17 abut at the upper horizontal rim of slide guide 24.2. Then, hinge pins 17 may easily be removed from the hinge receptacle 24 via insertion sections 24.1.

1-11. (canceled)

12. A cooling device for a control cabinet having a housing which comprises an opening into which a fan assembly having a support and a fan can be inserted, wherein the support can be detachably connected to the housing, wherein the support is pivotally connected to the housing via a hinge assembly having at least one hinge pin and at least one hinge receptacle and that the support can be pivoted between an installation position and a parking position.

13. The cooling device of claim 12, wherein the hinge pin is displaceable within an elongated hole-like hinge receptacle and the hinge receptacle comprises an insertion section through which the hinge pin can be moved into or out of the hinge receptacle.

14. The cooling device of claim 12, wherein in the installation position of the support, the hinge pin is held in a parking receptacle of the hinge receptacle and in the hinged down position of the support, the hinge pin is displaced into a pivoted receptacle and is form-fittingly held therein.

15. The cooling device of claim 12, wherein the hinge receptacle comprises a slide guide in which the hinge pin can be displaced between a position associated with the installation position and a de-installation position.

16. The cooling device of claim 12, wherein the housing comprises a wall delimited by two opposite rims, the rims are bent from the wall and extend therefrom on the back side, and the rims respectively comprise either a hinge receptacle or a hinge pin.

17. The cooling device of claim 12, wherein the support comprises a ventilation grille integrally molded thereto.

18. The cooling device of claim 12, wherein the support comprises an air outlet cross section which is delimited by a nozzle flange integrally molded to the support.

19. The cooling device of claim 12, wherein the support comprises screw domes protruding from its rear side by which a support plate is connected and the support plate receives the fan exchangeably.

20. The cooling device of claim 12, wherein the support comprises a cover which at least partly covers the opening of the housing, side parts are directly or indirectly molded to the cover which extend beyond the cover on its back side and which protrude through the opening in an installed state of the support, and the side parts carry the hinge pins or the hinge receptacles.

21. The cooling device of claim 12, wherein the pivot axis of the pivot linkage extends in the region of the back side of the cover of the support.

22. The cooling device of claim 12, wherein the support can be screw-fastened on opposite sides to the housing while resting at a front side of a wall of the housing with one side and resting at a back side with the other side.
